(19) United States
(12) Patent Application Publication
(10) Pub. No.: US 2014/0162463 A1
(43) Pub. Date: Jun. 12, 2014

(54) PLASMA ETCHING METHOD AND PLASMA ETCHING APPARATUS

(71) Applicant: Tokyo Electron Limited, Tokyo (JP)

(72) Inventor: Ryuichi TAKASHIMA, Miyagi (JP)

(73) Assignee: Tokyo Electron Limited, Tokyo (JP)

(21) Appl. No.: 14/098,648

(22) Filed: Dec. 6, 2013

Related U.S. Application Data
(60) Provisional application No. 61/739,297, filed on Dec. 19, 2012.

(30) Foreign Application Priority Data
Dec. 12, 2012 (JP) 2012-271790

(51) Int. Cl. H01L 21/3065; H01J 37/32

(52) U.S. Cl. CPC H01L 21/3065; H01J 37/32449
USPC 438/714; 156/345.26

(57) ABSTRACT

A plasma etching method is provided for etching a semiconductor substrate with plasma using a metal mask that is patterned on the semiconductor substrate. The plasma etching method includes a first etching step of controlling a pressure within a chamber to a first pressure and etching the semiconductor substrate inside the chamber under the first pressure using a plasma generated from a fluorine-containing gas; and a second etching step to be performed after the first etching step, the second etching step including controlling the pressure within the chamber to a second pressure, which is higher than the first pressure, and etching the semiconductor substrate inside the chamber under the second pressure using the plasma generated from the fluorine-containing gas.

### CROSS-REFERNCE TO RELATED APPLICATIONS

The present application is based on and claims priority to Japanese Patent Application No. 2012-271790 filed on Dec. 12, 2012, and U.S. Provisional Patent Application No. 61/739,297 filed on Dec. 19, 2012, the entire contents of which are hereby incorporated by reference.

### BACKGROUND OF THE INVENTION

1. Field of the Invention

The present invention relates to a plasma etching method and a plasma etching apparatus.

2. Description of the Related Art

Microfabrication of a mesh member used in a liquid-immersion exposure apparatus involves forming deep holes through etching. Specifically, plasma etching is performed to form several tens of thousands of holes with a diameter φ of 60 μm and a depth of approximately 100 μm on a silicon carbide (SiC) layer. Such a deep-hole etching process requires use of a high selectivity mask such a nickel (Ni) mask or some other metal mask. For example, Japanese Laid-Open Patent Publication No. 2008-288475 discloses a technique for etching a SiC film using a Ni mask.

In the case of etching a SiC layer using a Ni mask, an internal pressure of a chamber is controlled to 15-50 mT in order to increase selectivity, and fluorine gas is used to perform plasma etching on the SiC layer. In such case, the outermost layer of the Ni mask may be etched during the etching process and micro-mask residue may be generated as a result.

### SUMMARY OF THE INVENTION

It is an object of at least one embodiment of the present invention to provide a plasma etching technique for etching a semiconductor substrate using a metal mask that enables an etching process to be performed at a high selectivity while preventing the generation of residue.

According to an embodiment of the present invention, a plasma processing method is provided for etching a semiconductor substrate with plasma using a metal mask that is patterned on the semiconductor substrate. The plasma etching method includes a first etching step of controlling a pressure within a chamber to a first pressure and etching the semiconductor substrate inside the chamber under the first pressure using a plasma generated from a fluorine-containing gas; and a second etching step to be performed after the first etching step, the second etching step including controlling the pressure within the chamber to a second pressure, which is higher than the first pressure, and etching the semiconductor substrate inside the chamber under the second pressure using the plasma generated from the fluorine-containing gas.

According to another embodiment of the present invention, a plasma etching apparatus is provided for etching a semiconductor substrate with plasma using a metal mask that is patterned on the semiconductor substrate. The plasma etching apparatus includes a gas supply source that supplies a fluorine-containing gas to a chamber; and a control unit that controls a plasma etching process that is performed inside the chamber, the plasma etching process including etching the semiconductor substrate using a plasma generated from the fluorine-containing gas. The control unit controls a pressure within the chamber to a first pressure and controls etching of the semiconductor substrate under the first pressure using the generated plasma. After etching the semiconductor substrate under the first pressure, the control unit controls the pressure within the chamber to a second pressure, which is higher than the first pressure, and controls etching of the semiconductor substrate under the second pressure using the generated plasma.

According to an aspect of the present invention, generation of residue may be prevented when etching a semiconductor substrate using a metal mask, and an etching process may be performed at a high selectivity.

### BRIEF DESCRIPTION OF THE DRAWINGS

FIG. 1 illustrates an overall configuration of a plasma processing apparatus according to an embodiment of the present invention;

FIG. 2 is a series of SEM images illustrating plasma etching results depending on the pressure and power used;

FIG. 3 is a graph illustrating a residue density depending on the pressure used in a plasma etching process according to an embodiment of the present invention;

FIG. 4 is a flowchart illustrating process steps of a plasma etching process according to an embodiment of the present invention; and

FIG. 5 is a series of SEM images illustrating an exemplary effect of a plasma etching process according to an embodiment of the present invention.

### DESCRIPTION OF THE PREFERRED EMBODIMENTS

In the following, illustrative embodiments of the present invention are described with reference to the accompanying drawings. Note that in the descriptions and drawings, features that are substantially identical are given the same reference numerals and overlapping explanations thereof are omitted.

[Plasma Etching Apparatus Overall Configuration]

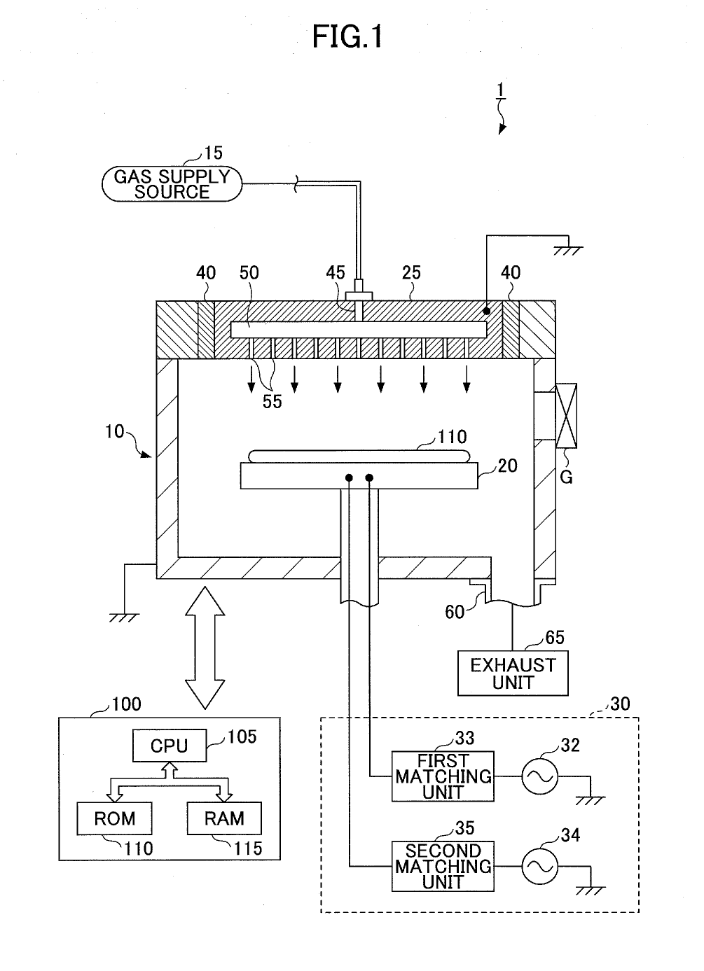

First, an overall configuration of a plasma etching apparatus according to an embodiment of the present invention is described below with reference to FIG. 1. FIG. 1 illustrates an overall configuration of a plasma etching apparatus 1 according to the present embodiment.

The illustrated plasma processing apparatus 1 of the present embodiment corresponds to a parallel plate type plasma etching apparatus that has an upper electrode and a lower electrode (susceptor) arranged to face each other within a chamber and is configured to supply a processing gas into the chamber from the upper electrode. FIG. 1 is a cross-sectional view of the plasma etching apparatus 1.

The plasma etching apparatus 1 includes a chamber 10 made of a conductive material such as aluminum and a gas supply source 15 that supplies an etching gas within the chamber 10. The chamber 10 is grounded. As one example of the etching gas, sulfur hexafluoride (SF₆) gas may be used.

The chamber 10 is electrically grounded, and a lower electrode 20 and an upper electrode 25 arranged parallel to and facing the lower electrode 20 are provided within the chamber 10. The lower electrode 20 also acts as a stage for holding a SiC substrate 110. The SiC substrate 101 is an example of a semiconductor substrate subject to etching.

The lower electrode 20 is connected to a power supply unit 30 that is configured to supply a dual frequency superimposed power. The power supply unit 30 includes a first high frequency power supply 32 that is configured to supply a first high frequency power at a first frequency (high frequency power for plasma generation) and a second high frequency power supply 34 that is configured to supply a second high frequency power at a second frequency that is lower than the first frequency (high frequency power for biasing). The first high frequency power supply 32 is electrically connected to the lower electrode 20 via a first matching unit 33. The second high frequency power supply 34 is electrically connected to the lower electrode 20 via a second matching unit 35.

The first matching unit 33 and the second matching unit 35 are respectively configured to match a load impedance to an internal (or output) impedance of the first high frequency power supply 32 and the second high frequency power supply 34. That is, the first matching unit 33 and the second matching unit 35 respectively operate to make the load impedance resemble (match) the internal impedance of the first high frequency power supply 32 and the second high frequency power supply 34 when plasma is generated within the chamber 10.

The upper electrode 25 has a shield ring arranged around its periphery and is mounted to a ceiling part of the chamber 10 via the shield ring 40. The upper electrode 25 may be electrically grounded as illustrated in FIG. 1, or the upper electrode 25 may be connected to a variable DC power supply (not shown) so that a predetermined direct current (DC) voltage may be applied to the upper electrode 25, for example.

A gas introduction port 45 for introducing gas from the gas supply source 15 is formed at the upper electrode 25. Also, a diffusion chamber 50 for diffusing the gas introduced via the gas introduction port 45 is formed within the upper electrode 25.

The upper electrode 25 has multiple gas supply holes 55 for supplying gas from the diffusion chamber 50 into the chamber 10. The supply holes 55 are arranged so that gas may be supplied between the upper electrode 25 and the SiC substrate 110 that is placed on the lower electrode 20.

Gas from the gas supply source 15 is supplied to the diffusion chamber 50 via the gas introduction port 45, and the gas is diffused at the diffusion chamber 50 to be distributed to the gas supply holes 55 and discharged therefrom toward the lower electrode 20. In this respect, the upper electrode 25 also acts as a shower head for supplying gas to the chamber 10.

The chamber 10 has an exhaust port 60 formed at its bottom face. The exhaust port 60 is connected to an exhaust unit 65 that is configured to evacuate air so that the interior of the chamber 10 may be maintained at a predetermined degree of vacuum. A gate valve G is arranged at a side wall of the chamber 10. The gate valve G is configured to open/close a load port upon loading/unloading the SiC substrate 110 into/out of the chamber 10.

The plasma etching apparatus 1 further includes a control unit 100 that controls overall apparatus operations. The control unit 100 includes a CPU (Central Processing Unit) 105, and a ROM (Read Only Memory) 110 and a RAM (Random Access Memory) as storage areas. The CPU 105 may execute a plasma etching process according to various recipes stored in the storage areas. The recipes may describe apparatus control information according to various processing conditions. For example, the recipes may include information relating to processing time, pressure (gas evacuation), high frequency power and voltage, processing gas flow rates of various types of processing gases, and chamber temperatures (e.g., upper electrode temperature, side wall temperature of processing chamber, ESC temperature). Note that the recipes describing such programs and processing conditions may be stored in a hard disk or a semiconductor memory, or they may be stored in a portable computer-readable storage medium such as a CD-ROM or a DVD and loaded to a predetermined location of a storage area, for example.

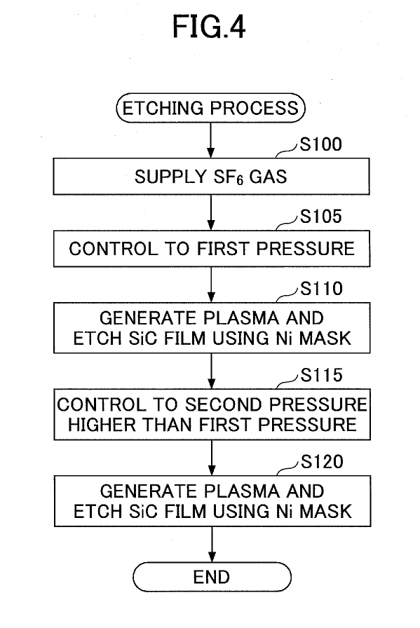

The plasma etching apparatus 1 as described above is configured to perform an etching process as illustrated in FIG. 4 (described below). In this case, first, the gate valve G is opened, and the SiC substrate 110 having a predetermined Ni mask pattern thereon is loaded into the chamber 10 by a transfer arm (not shown), for example, and is placed on the lower electrode 20. Then, the control unit 100 controls the operations of various components to have gas and the first and second high frequency powers supplied to the chamber 10 so that a desired plasma may be generated. The generated plasma is then used to perform a desired plasma etching process to form several tens of thousands of holes with a diameter φ of 60 μm and a depth of approximately 100 μm on the SiC substrate 110, for example. The overall configuration of the plasma etching apparatus 1 according to the present embodiment has been described above.

[SiC Layer Etching Using Metal Mask]

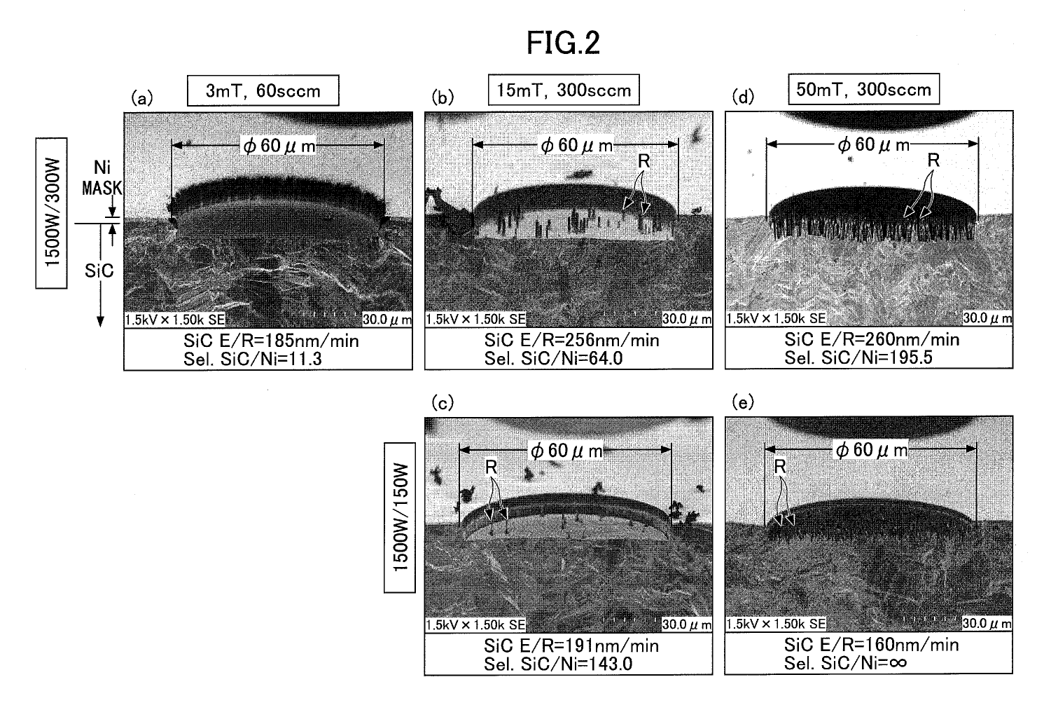

Next, plasma etching results that depend on the pressure and power used are described with reference to FIG. 2. FIG. 2 is a series of SEM (scanning electron microscope) images illustrating results of etching a SiC layer into a pattern of a Ni mask using the plasma etching apparatus 1. The processing conditions used in each etching process are indicated below.

<Etching Process of FIG. 2 (a)>

(Processing Conditions)

| | |
|---|---|
| Pressure | 3 mT (0.400 Pa) |
| Power | First high frequency power: 1500 W |
| | Second high frequency power: 300 W |
| Magnetic Field | 150 G (1.5⁻² T) |
| Gas Flow Rate | SF₆ gas, 60 sccm |
| Etching Time | 30 minutes |

(Etching Process Result)

Referring to the SEM image of FIG. 2 (a), it can be appreciated that residue is not generated at an etched portion corresponding to a hole with a diameter φ of 60 μm when an extremely low pressure of 3 mT is used. That is, residue may be prevented from being generated from a modified layer of the outermost surface of the Ni mask when the pressure is controlled to 3 mT.

On the other hand, under an extremely low pressure of 3 mT, the selectivity (Sel.) of the Ni mask with respect to the SiC layer is reduced to approximately 11 (SiC/Ni=11.3). Because the thickness of the Ni mask is approximately 2 μm, unless the selectivity of the Ni mask is at least 50, the Ni mask may be etched away and gone before a hole with a depth of 100 μm can be formed.

As can be appreciated from above, in an etching process where an extremely low pressure of 3 mT is used, although residue generation can be prevented, the Ni mask may be gone before a hole with a depth of 100 μm can be formed.

<Etching Process of FIG. 2 (b)>

(Processing Conditions)

| | |
|---|---|
| Pressure | 15 mT (2.00 Pa) |
| Power | First high frequency power: 1500 W |
| | Second high frequency power: 300 W |
| Magnetic Field | 150 G (1.5⁻² T) |
| Gas Flow Rate | SF₆ gas, 300 sccm |
| Etching Time | 30 minutes |

(Etching Process Result)

Referring to the SEM image of FIG. 2 (b), it can be appreciated that residues R are generated at an etched portion corresponding to a hole with a diameter φ of 60 μm. The residues R are substantially upright and their heights are substantially uniform. The residues R are generated from the outermost layer of the Ni mask being turned into a native oxide film such as a NiO film as a result of exposure to the atmosphere or execution of a previous process, for example. As can be appreciated, when the pressure is controlled to 15 mT, extremely hard residues R are generated from a modified layer of the outermost surface of the Ni mask and are dispersed within an etched hole as micro mask residues.

On the other hand, under a pressure of 15 mT, the selectivity (Sel.) of the Ni mask with respect to the SiC layer is 64. In this case, because the selectivity is above 50, the Ni mask may not be gone before a hole with a depth of 100 μm is formed.

As can be appreciated from the above, in the etching process using a pressure of 15 mT, a hole with a depth of 100 μm may be formed before the Ni mask is etched away and gone, but residues R are generated from the modified layer of the outermost surface of the Ni mask.

<Etching Process of FIG. 2 (c)>

(Processing Conditions)

| | |
|---|---|
| Pressure | 15 mT (2.00 Pa) |
| Power | First high frequency power: 1500 W |
| | Second high frequency power: 150 W |
| Magnetic Field | 150 G (1.5⁻² T) |
| Gas Flow Rate | SF₆ gas, 300 sccm |
| Etching Time | 30 minutes |

Note that the processing conditions of FIG. 2 (c) differ from the processing conditions of FIG. 2 (b) in that the second high frequency power used for biasing is reduced from 300 W to 150 W.

(Etching Process Result)

Referring to the SEM image of FIG. 2 (c), it can be appreciated that residues R are generated at an etched portion corresponding to a hole with a diameter φ of 60 μm. However, because the second high frequency power is set lower than FIG. 2 (b), effects of sputtering the Ni mask are reduced, and as a result, the amount of residues R is reduced compared to FIG. 2 (b). That is, the modified layer of the outermost surface of the Ni mask may be prevented from being supplied into the etched hole through sputtering.

On the other hand, the selectivity (Sel.) of the Ni mask with respect to the SiC layer is increased to 143.0, which is higher than the selectivity in FIG. 2 (b). As described above, in the etching process of FIG. 2 (c), the effects of sputtering the Ni mask are reduced compared to the case of FIG. 2 (b). It is believed that this in turn causes such an increase in the selectivity.

As can be appreciated from the above, in the etching process using a pressure of 15 mT, a hole with a depth of 100 μm may be formed before the Ni mask is etched away and gone, regardless of whether the second high pressure power is set to 150 W or 300 W. However, residues R are generated from the modified layer of the outermost surface of the Ni mask in both cases.

<Etching Process of FIG. 2 (d)>

(Processing Conditions)

| | |
|---|---|
| Pressure | 50 mT (6.67 Pa) |
| Power | First high frequency power: 1500 W |
| | Second high frequency power: 300 W |
| Magnetic Field | 150 G (1.5⁻² T) |
| Gas Flow Rate | SF₆ gas, 300 sccm |
| Etching Time | 30 minutes |

Note that the processing conditions of FIG. 2 (d) differ from the processing conditions of FIG. 2 (b) in that the pressure is increased from 15 mT to 50 mT.

(Etching Process Result)

Referring to the SEM image of FIG. 2 (d), it can be appreciated that more residues R are generated at an etched portion corresponding to a hole with a diameter φ of 60 μm. That is, more residues are generated when the pressure is raised from 15 mT to 50 mT. On the other hand, the selectivity (Sel.) of the Ni mask with respect to the SiC layer is increased to 195.5.

As can be appreciated from the above, in the etching process using a pressure of 50 mT, a hole with a depth of 100 μm may be formed before the Ni mask is etched away and gone, but a large amount of residues R are generated from the modified layer of the outermost surface of the Ni mask.

<Etching Process of FIG. 2 (e)>

(Processing Conditions)

| | |
|---|---|
| Pressure | 50 mT (6.67 Pa) |
| Power | First high frequency power: 1500 W |
| | Second high frequency power: 150 W |
| Magnetic Field | 150 G (1.5⁻² T) |
| Gas Flow Rate | SF₆ gas, 300 sccm |
| Etching Time | 30 minutes |

Note that the processing conditions of FIG. 2 (e) differ from the processing conditions of FIG. 2 (d) in that the biasing power (second high frequency power) is reduced from 300 W to 150 W.

(Etching Process Result)

Referring to the SEM image of FIG. 2 (e), it can be appreciated that even more residues R are generated at an etched portion corresponding to a hole with a diameter φ of 60 μm.

As can be appreciated from the above, in the etching process using a pressure of 50 mT, a large amount of residues R are generated from the modified layer of the outermost surface of the Ni mask regardless of whether the second high pressure power is set to 150 W or 300 W.

Based on the above results, it may be supposed that the generation of residues R is caused by the dispersion of a Ni native oxide film from the modified layer of the outermost surface of the Ni mask. Also, it can be appreciated that etching the SiC layer at an extremely low pressure of approximately 3 mT produces, favorable results in terms of preventing the generation of residues R.

Also, taking into account the substantial uniformity in height of the residues R, it may be supposed that a modified layer with a predetermined thickness is dispersed from the outermost surface of the Ni mask to become a micro mask and cause the generation of residues R. That is, the outermost surface of the Ni mask is modified through exposure to the atmosphere or the execution of a previous process, and this modified layer (e.g., Ni native oxide film) presumably causes the generation of the residues R. Accordingly, a layer several micrometers (um) below the outermost surface of the Ni mask that is not modified may not cause generation of the residues R.

Thus, as a measure for preventing the generation of residues R, a first etching step may be executed while controlling the pressure within the chamber 10 to approximately 3 mT so that a Ni native oxide film dispersed from the modified layer of the outermost surface of the Ni mask may be immediately evacuated under an extremely low pressure.

On the other hand, because the layer of the Ni mask several micrometers below the surface is not modified as described above, residues R may not be generated even if this lower layer below the modified layer of the Ni mask is etched during the etching process. Also, note that in the present embodiment, deep holes at a depth of approximately 100 μm have to be formed. Thus, the selectivity of the Ni mask has to be at least 50. Accordingly, after the modified layer of the Ni mask is etched away in the first etching step, a second etching step may be executed by raising the pressure within the chamber 10 to at least 15 mT so that the selectivity of the Ni mask may be at least 50.

As a further measure for preventing the generation of residues R, the second high frequency power corresponding to the biasing power may be reduced in the first etching step in order to prevent sputtering of the modified layer, for example. In another example, the second high frequency power may be set to 150 W in both the first etching step and the second etching step. Note, however, that when the second high frequency power is set to 300 W in the first etching step, the required etching time of the first etching step may be approximately 5 minutes. On the other hand, when the second high frequency power is set to 150 W in the first etching step, the required etching time may be longer than 5 minutes.

Note that FIG. 2 also indicates the SiC film etching rates (SiC E/R) of the etching processes (a)-(e). As can be appreciated, the etching rate tends to increase as the second high frequency power is increased.

[Residue Density-Pressure Relationship]

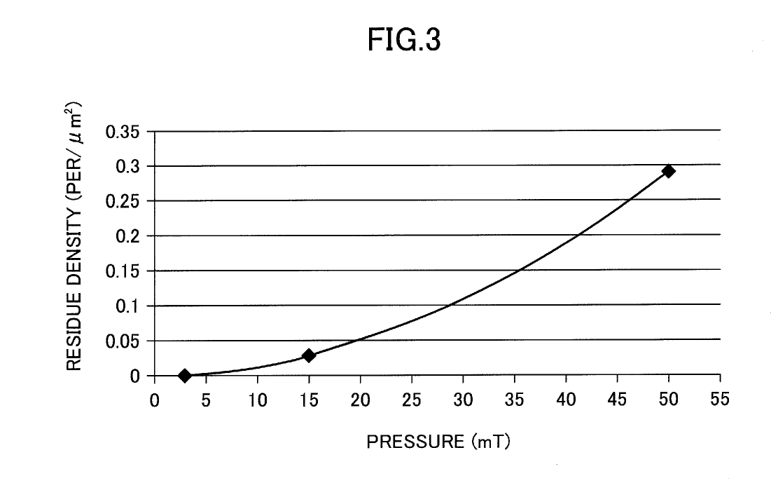

FIG. 3 is a graph illustrating the residue density depending on the pressure used in a plasma etching process according to an embodiment of the present invention. In the graph of FIG. 3, the horizontal axis represents the pressure within the chamber 10 and the vertical axis represents the residue density (number of residues per μm²).

Note that the etching process of FIG. 3 was performed under the following processing conditions.

| | |
|---|---|
| Pressure | Variable |
| Power | First high frequency power: 1500 W |
| | Second high frequency power: 300 W |
| Magnetic Field | 150 G (1.5⁻² T) |
| Gas Flow Rate | SF₆ gas, 60-300 sccm |
| Etching Time | 30 minutes |

Note that in the present etching process, the flow rate of SF₆ gas is adjusted and the pressure is varied. As can be appreciated, in the present example, the residue density is substantially close to 0 (zero) when the pressure is within the range of 2 mT (0.267 Pa) to 5 mT (0.667 Pa). Accordingly, in the first etching step, the pressure (first pressure) is preferably set to 2-5 mT so that substantially no residues would be generated.

Also, based on the experimental results illustrated in FIG. 2, in the second etching step, the pressure (second pressure) is preferably to 15-100 mT so that the selectivity may be at least 50. However, it can be appreciated from the experimental results of FIG. 2 that the amount of residues R generated increases as the pressure is increased. Accordingly, based on the residue density depending on the pressure illustrated in FIG. 3, the second pressure used in the second etching step is preferably set to 15-50 mT so that the selectivity may be at least 50 and the residue density may be less than 0.3 (per μm²).

[Etching Method]

Based on the experimental results illustrated in FIGS. 2 and 3, in a plasma etching method according to an embodiment of the present invention that involves etching a substrate with plasma using a metal mask such as a Ni mask that is patterned on the substrate, etching is preferably performed in two steps. In the following, the plasma etching method according to the present embodiment is described with reference to FIG. 4. FIG. 4 is a flowchart illustrating process steps of the plasma etching method according to the present embodiment. The execution of the process steps of FIG. 4 are primarily controlled by the control unit 100.

When a SiC substrate is introduced into the chamber 10 and the etching process of the present embodiment is started, first, the control unit 100 supplies SF₆ gas as the etching gas into the chamber 10 (S100), and controls the pressure within the chamber 10 to a first pressure (S105). In the present embodiment, the first pressure is set equal to a value within the range of 2 mT (0.267 Pa) to 5 mT (0.667 Pa).

Next, the control unit 100 applies the first high frequency power and the second high frequency power to the lower electrode 20. In the present embodiment, the first high frequency power and the second high frequency power are set equal to 1500 W and 150 W (or 300 W), respectively. The first high frequency power is used to generate fluorine plasma from SF₆ gas. The generated plasma is used to etch a Sic film for five minutes, for example, using an Ni mask (S110). The above etching time may be determined based on the time required for the outermost modified layer of the Ni mask to be etched.

Next, the control unit 100 controls the pressure within the chamber 10 to be increased from the first pressure to the second pressure, which is higher than the first pressure (S115). In the present embodiment, the second pressure is preferably set equal to a value within the range of 15 mT (2.00 Pa) to 100 mT (13.3 Pa), and more preferably within the range of 15 mT (2.00 Pa) to 50 mT (6.67 Pa). Under the second pressure, the plasma generated from the SF₆ gas is used to etch the SiC film using the Ni mask for a time period that is required to etch a hole at a depth of 100 μm, for example (S120) after which the present etching process is ended.

As described above, in the present embodiment, the first etching step is performed under an extremely low pressure so that residues may not be generated while etching the outermost modified layer of the Ni mask, and in this way, dispersion of the Ni modified layer corresponding to the source of residue may be prevented. Also, by etching away the outermost modified layer of the Ni mask in the first etching step, residues may not be generated even when the pressure is raised in the second etching step because the modified layer of the Ni mask would already be gone. Accordingly, in the second etching step, high selectivity of the Ni mask may be maintained under a state in which residue generation is deterred. Thus, by performing the two-step etching method including the first etching step and the second etching step of the present embodiment, deep holes with a depth of 100 μm or greater may be formed without generating residues, for example.

[Exemplary Effects]

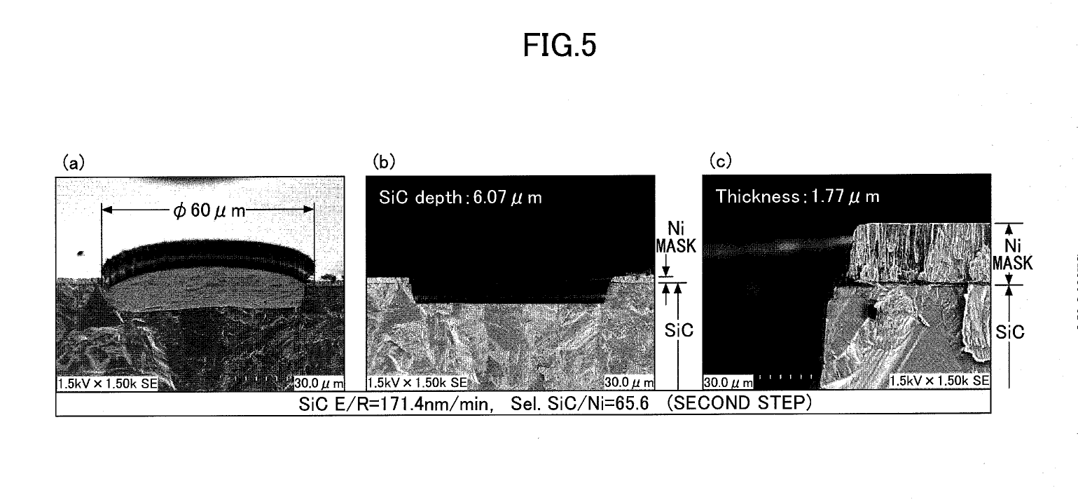

FIG. 5 illustrates exemplary effects of the plasma etching method of the present embodiment. The SEM images shown in FIG. 5 illustrate results of performing the first etching steps and the second etching step under the processing conditions indicated below.

<Processing Conditions>

(First Etching Step)

| | |
|---|---|
| Pressure | 3 mT (0.400 Pa) |
| Power | First high frequency power: 1500 W |
| | Second high frequency power: 300 W |
| Magnetic Field | 150 G (1.5⁻² T) |
| Gas Flow Rate | SF₆ gas, 60 sccm |
| Etching Time | 5 minutes |

(Second Etching Step)

| | |
|---|---|
| Pressure | 15 mT (2.00 Pa) |
| Power | First high frequency power: 1500 W |
| | Second high frequency power: 150 W |
| Magnetic Field | 150 G (1.5⁻² T) |
| Gas Flow Rate | SF₆ gas, 300 sccm |
| Etching Time | 30 minutes |

<Processing Results>

According to the etching method using the above processing conditions, in the first etching step, etching is performed under an extremely low pressure of 3 mT so that residues may not be generated, and the outermost modified layer of the Ni mask is removed. Then, in the second etching step, etching is performed under a higher pressure of 15 mT so that the selectivity may be increased. In the second etching step, residues may not be generated even when pressure is raised to 15 mT because the outermost modified layer of the Ni mask is removed.

As can be appreciated from FIG. 5 (a), residues R were not generated within an etched hole with a diameter φ of 60 μm after executing the first etching step and the second etching step of the present embodiment. Note that FIG. 5 (b) is a vertical cross-sectional view of the hole illustrated in FIG. 5 (a), and FIG. 5 (c) is an enlarged view of a portion of FIG. 5 (b).

Also, note that the selectivity in the second etching step was 65.6, which is an adequately high selectivity for forming the desired deep holes.

As can be appreciated from above, according to an aspect of the etching method of the present embodiment, by performing the first etching step and the second etching step, a concavo-convex feature with a depth of 90-100 μm may be formed on a substrate, or a through hole with a length of 90-100 μm may be formed through the substrate without causing generation of residues.

(Practical Applications)

In the following, exemplary practical applications of the etching method of the present embodiment are described. In one example, the etching method of the present embodiment may be applied to microfabrication of a mesh member used in a liquid immersion exposure apparatus. By implementing the first etching step and the second etching step of the etching method of the present embodiment, several tens of thousands of holes with a diameter φ of 60 μm and a depth of approximately 100 μm may be formed on a SiC substrate without causing generation of residues. By applying the etching method of the present embodiment, several tens of thousands of holes may be simultaneously formed through etching. In this way, the processing speed for forming the holes may be accelerated compared to a case of forming each of the several thousands of holes individually using laser, for example, and productivity may be improved as a result.

In another example, the etching method of the present embodiment may be applied to microfabrication of protrusions of an electrostatic chuck surface. Note that preventing the generation of residue may be particularly important in the case of etching holes that do not penetrate through a substrate, for example. Thus, the etching method of the present embodiment may be useful for forming a concavo-convex feature with a depth of 90 μm or greater on a substrate without causing generation of residues.

[Modification]

According to one exemplary modification of the etching method described above, the first etching step and the second etching step may be successively performed one after the other. That is, the first etching step and the second etching step may be repeated multiple times in the following sequence: first etching step→second etching step→first etching step→second etching step, and so forth.

The above modified etching method may be applied in a case where the SiC substrate is exposed to the atmosphere during the etching process, for example. In this case, the first etching step may be performed under the first pressure immediately after the substrate is exposed to the atmosphere. In this way, a modified layer formed on the surface of the Ni mask may be removed by the first etching step without causing generation of residues each time the Ni mask surface is oxidized through exposure to the atmosphere, for example.

The above modified etching method involving successive execution of the first etching step and the second etching step may be used even in a case where the SiC substrate is not exposed to the atmosphere. For example, in case where some particle is generated during an etching process, the first etching step may be implemented to actively discharge the particle outside the chamber 10 under a lower pressure. That is, the second etching step may be periodically intercepted by the first etching step in order to discharge particles generated within the chamber 10, for example.

Although the plasma etching method and the plasma etching apparatus of the present invention are described above with reference to certain illustrative embodiments, the present invention is not limited to these embodiments but includes numerous variations and modifications that may be made without departing from the scope of the present invention. The present invention also encompasses all combinations of the above embodiments and modifications to the extent practicable.

For example, a semiconductor substrate on which the plasma etching process of the present invention may be performed is not limited to a silicon carbide (SiC) substrate. The plasma etching process of the present invention may also be performed on a silicon (Si) substrate or a gallium nitride (GaN) substrate, for example.

Also, a metal mask that is patterned on the substrate to be used in the plasma etching process of the present invention is not limited to a Ni mask, but may also be an aluminum (Al) mask or a chrome (Cr) mask, for example.

Also, the etching gas used in the first etching step and the second etching step is not limited to sulfur hexafluoride (SF₆) gas, but may be some other type of fluoride-containing gas. Other exemplary fluoride-containing gases that may be used as the etching gas include carbon tetrafluoride (CF₄) gas, nitrogen trifluoride (NF₃) gas, and combinations of these fluorine gases. Further, chlorine (Cl₂) gas or hydrogen bromide (HBr) may be used as a processing gas, for example.

Also, the present invention may use various means for generating plasma including, but not limited to, capacitively coupled plasma (CCP) generation systems, inductively coupled plasma (ICP) generation systems, helicon wave plasma (HWP) generation systems, surface wave plasma generations systems including radial line slot antenna microwave plasma generation systems and slot plane antenna

(SPA) plasma systems, electron cyclotron resonance plasma generation systems, and remote plasma generation systems using the above plasma generation systems, for example.

What is claimed is:

1. A plasma etching method for etching a semiconductor substrate with plasma using a metal mask that is patterned on the semiconductor substrate, the method comprising:
a first etching step including controlling a pressure within a chamber to a first pressure and etching the semiconductor substrate inside the chamber under the first pressure using a plasma generated from a fluorine-containing gas; and
a second etching step to be performed after the first etching step, the second etching step including controlling the pressure within the chamber to a second pressure, which is higher than the first pressure, and etching the semiconductor substrate inside the chamber under the second pressure using the plasma generated from the fluorine-containing gas.

2. The plasma etching method as claimed in claim 1, wherein the first pressure is equal to a value within a range of 2 mT (0.267 Pa) to 5 mT (0.667 Pa).

3. The plasma etching method as claimed in claim 1, wherein the second pressure is equal to a value within a range of 15 mT (2.00 Pa) to 100 mT (13.3 Pa).

4. The plasma etching method as claimed in claim 3, wherein the second pressure is equal to a value within a range of 15 mT (2.00 Pa) to 50 mT (6.67 Pa).

5. The plasma etching method as claimed in claim 1, wherein the metal mask includes at least one of nickel (Ni), aluminum (Al), and chrome (Cr).

6. The plasma etching method as claimed in claim 1, wherein the semiconductor substrate includes at least one of silicon carbide (SiC), silicon (Si), and gallium nitride (GaN).

7. The plasma etching method as claimed in claim 1, wherein
the first etching step and the second etching step include forming a concavo-convex feature with a depth greater than or equal to 90 μm on the substrate, or forming a through hole with a length greater than or equal to 90 μm through the substrate.

8. The plasma etching method as claimed in claim 1, wherein the first etching step and the second etching step include forming a through hole with a length greater than or equal to 90 μm through the substrate.

9. The plasma etching method as claimed in claim 1, wherein
the first etching step includes etching an outermost modified layer of the metal mask; and
the second etching step is performed after the modified layer is etched in the first etching step.

10. The plasma etching method as claimed in claim 1, wherein the first etching step and the second etching step are repeatedly performed.

11. A plasma etching apparatus for etching a semiconductor substrate with plasma using a metal mask that is patterned on the semiconductor substrate, the plasma etching apparatus comprising:
a gas supply source that supplies a fluorine-containing gas to a chamber; and
a control unit that controls a plasma etching process that is performed inside the chamber, the plasma etching process including etching the semiconductor substrate using a plasma generated from the fluorine-containing gas;
wherein the control unit controls a pressure within the chamber to a first pressure and controls etching of the semiconductor substrate under the first pressure using the generated plasma; and
after etching the semiconductor substrate under the first pressure, the control unit controls the pressure within the chamber to a second pressure, which is higher than the first pressure, and controls etching of the semiconductor substrate under the second pressure using the generated plasma.
